(19) United States
(12) Patent Application Publication
(10) Pub. No.: US 2006/0057766 A1
(43) Pub. Date: Mar. 16, 2006

(54) Method for preparation of semiconductive films

(76) Inventors: Quanxi Jia, Los Alamos, NM (US); Lin Song Li, Fayetteville, AR (US)

Correspondence Address: Bruce H. Cottrell;Los Alamos National Laboratory, LC/IP, MS A187, Los Alamos, NM, 87545, US

(21) Appl. No.: 10/615,645

(22) Filed: Jul. 8, 2003

(51) Int. Cl. H01L 21/00

(52) U.S. Cl. 438/85; 438/104; 438/86

(57) ABSTRACT

A polymer assisted solution process for deposition of semiconductive thin films is presented. The process can be organic solvent-free. The process includes solutions of necessary metal precursors and soluble polymers. After a coating operation, the resultant coating is fired at high temperatures to yield optical quality metal oxide thin films that can be converted to semiconductive thin films.

### STATEMENT REGARDING FEDERAL RIGHTS

This invention was made with government support under Contract No. W-7405-ENG-36 awarded by the U.S. Department of Energy. The government has certain rights in the invention.

### FIELD OF THE INVENTION

The present invention relates to a deposition technique for semiconductive films and more particularly to the polymer assisted deposition of semiconductive films, especially thin semiconductive films. The polymer assisted deposition can be accomplished in an aqueous solution process.

### BACKGROUND OF THE INVENTION

Semiconductive films are used for photovoltaic and electro-optical devices. Such semiconductive materials have been previously deposited in the form of films by techniques such as reactive sputtering, co-evaporation techniques and chemical vapor deposition techniques.

Several methods of manufacturing thin-film solar cells are described by U.S. Pat. Nos. 4,735,644, 5,538,903 (a paste deposition process), U.S. Pat. Nos. 5,728,231, 5,828,117 and 5,994,163. Despite these various methods, improvements and new techniques have continually been sought.

An object of the present invention is to provide a process of forming semiconductive thin films through an initial chemical solution deposition method of metal oxide thin films followed by conversion of the metal oxide to a sulfide, selenide, and the like.

### SUMMARY OF THE INVENTION

To achieve the foregoing and other objects, and in accordance with the purposes of the present invention, as embodied and broadly described herein, the present invention provides for a process of preparing a semiconductive film including applying a solution including a soluble polymer and a soluble metal precursor onto a substrate to form a polymer and metal-containing layer thereon, treating said substrate including said polymer and metal-containing layer for a time to form a coherent composite film, heating sufficient to remove said polymer from said composite film and form a metal oxide film, and reacting said metal oxide film with a sulfur-, selenium- or tellurium-containing gas under conditions sufficient to form a semiconductive film. In one embodiment of the invention, the solution is an aqueous solution having a pH of from about 4 to about 7 and characterized as organic-solvent free.

The present invention further provides for preparation of a metal oxide thin film by deposition of a solution including a metal salt and a soluble polymer, followed by the drying and calcination so as to form a polymer-free metal oxide thin film, and subsequent conversion of the metal oxide to a semiconductive material such as a sulfide, selenide or telluride.

The present invention further provides a process for preparation of a semiconductive thin film, the process characterized as organic-solvent free.

### BRIEF DESCRIPTION OF THE DRAWINGS

FIG. 1 shows a flow diagram of a fabrication process of semiconductive films in accordance with the present invention.

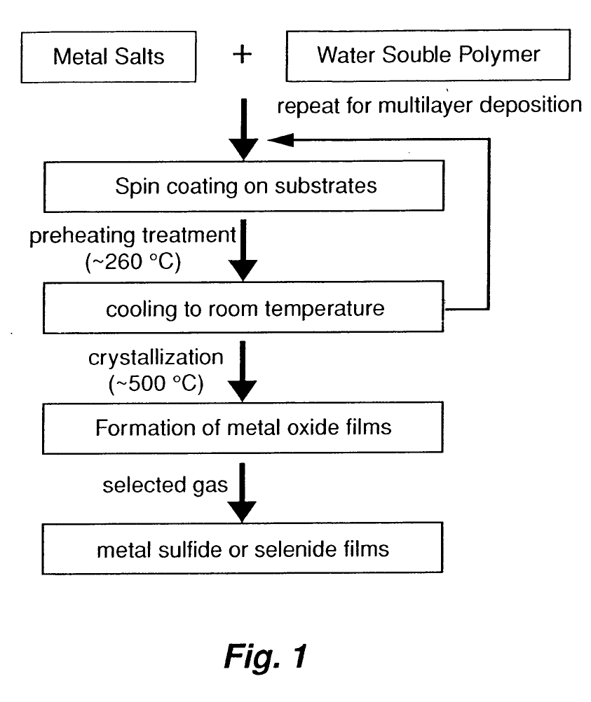

FIG. 2 shows a plot of a current-voltage characteristic of a CdS film on a conductive indium-tin oxide (ITO) substrate, the CdS film made in accordance with the present invention. The inset shows the current-voltage curve of the material while light illumination is on and off.

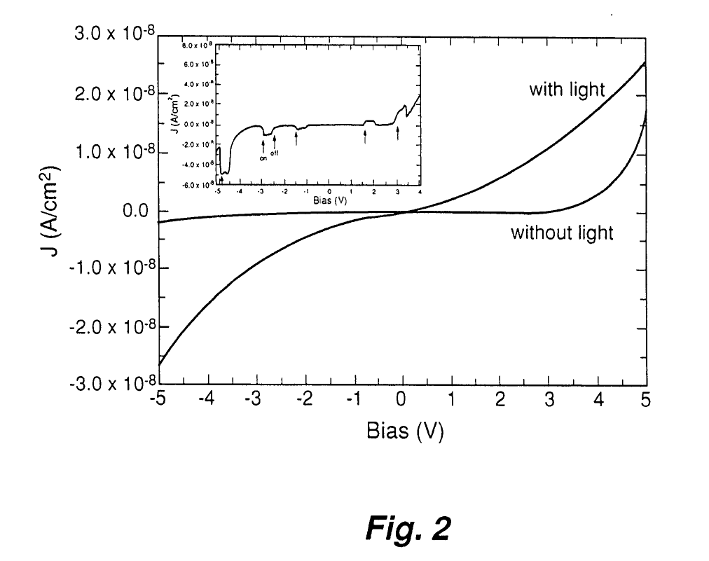

FIG. 3 shows a plot of a current-voltage characteristic of a CdS—TiO₂ film on ITO made in accordance with the present invention.

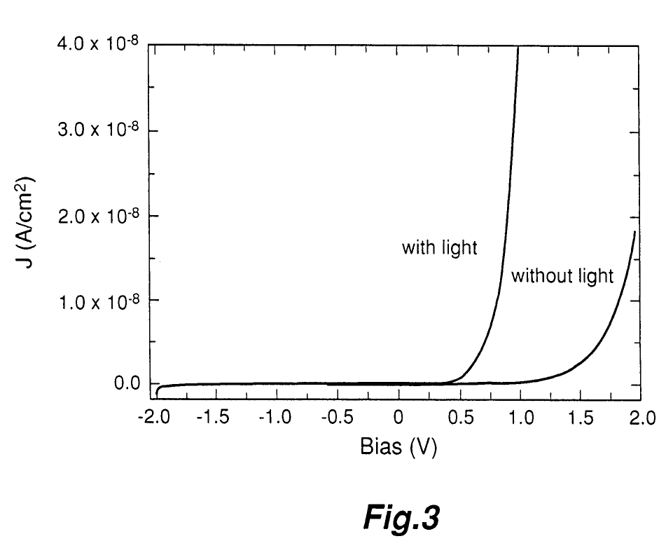

FIG. 4 shows a plot of a surface photovoltage spectrum of a CdS film on ITO made in accordance with the present invention.

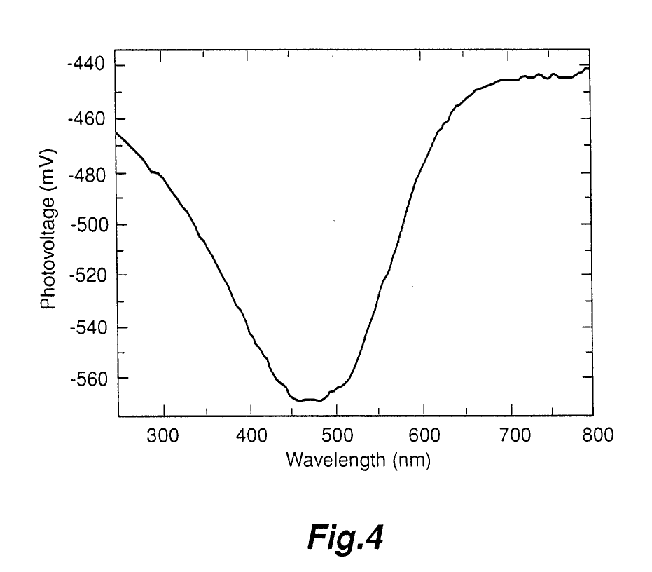

FIG. 5 shows a plot of a surface photovoltage spectrum of a CdSe film on ITO made in accordance with the present invention.

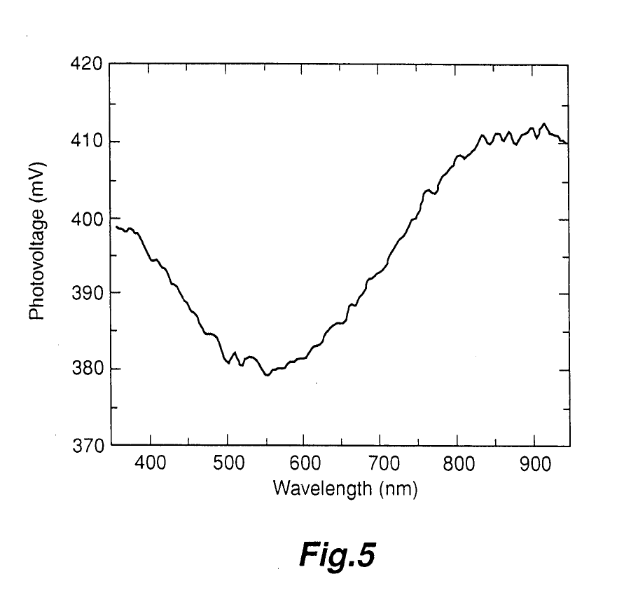

### DETAILED DESCRIPTION

The present invention is concerned with a process for preparing semiconductive materials, such as semiconductive films, especially semiconductive thin films from a polymer-assisted process from polymer-containing solutions, preferably from a polymer-assisted process from polymer-containing aqueous solutions, and in at lease one embodiment, from an organic solvent-free process. These films can be used to fabricate solar cell and electro-optical devices. The present process also allows preparation of semiconductive films with a controllable layered structure such as pn junctions, doped materials such as for different conduction types, and desired electrical properties.

In a first stage of preparing semiconductive films, materials deposited from a solution, e.g., an aqueous solution, form metal oxide films. At that stage, metal ion hydrolysis and solution viscosity need to be addressed. Hydrolytic reactions in water can be avoided by using ligands to block the access of water molecules to the metal ions. This effectively changes the hydrolytic properties of metal ions and makes very stable metal ion complexes in aqueous solution.

The metal chelates used in the present invention should be soluble and can be water-soluble. Among suitable metal chelates are included, e.g., cadmium nitrate tetrahydrate, zinc nitrate hydrate, lead acetate trihydrate, copper (II) chloride dihydrate, indium (III) chloride, titanium (IV) (triethanolaminato)-isopropoxide, bis(ammonium lactato)dihydride and the like. Titanium bis(ammonium lactato)dihydride or dihydroxybis(ammonium lactato)titanium (CAS No. 65104-06-5) as a soluble, e.g., water soluble, source of titanium is sold by E. I. DuPont de Nemours and Company under the name Tyzor LA®, which contains 13.7 weight/weight percent or 16.6 weight/volume percent TiO₂. Several other soluble titanium chelates are available commercially. Similar soluble chelates are also available for other desired metals such as cadmium, copper, gallium, indium, zinc, titanium, tin, lead, aluminum, and the like. Combinations of metal such as zinc and cadmium, cadmium and indium, cadmium and titanium, gallium and copper, zinc and titanium, layered metals such as cadmium/zinc, cadmium/copper, titanium/zinc, and titanium/cadmium can be used as well. Cadmium is especially preferred as the metal for preparation of CdO films. CuAlO₂ can be made as p-type conductive electrode. CdInOₓ films have been prepared from combinations of cadmium and indium. CdO/CuO, CdO/ZnO, and CdO/TiO₂ films have been prepared as heterojunction structures. Mixture metal oxide films, such as ZnₓCd₁₋ₓO, CuₓCd₁₋ₓO, and CuGa₁₋ₓInₓO_{y} can be prepared also.

In order to have good processing characteristics, the metal precursor solution should have a suitable viscosity. Instead of relying on uncontrollable viscosity generated by hydrolysis of metal oxo compounds, soluble polymers are used to yield the viscosity desired for thin film processing. The soluble polymers are water-soluble for aqueous processing. While not wishing to be bound by the present explanation, it may be that in addition to providing the suitable viscosity, the soluble polymer also functions as a ligand thereby enhancing the solubility of the metal compounds and/or stabilizing the metal ions from hydrolysis. In an alternative embodiment, suitable viscosity can be provided by the addition of an organic additive such as a polymeric colloidal latex.

In the present invention metal ions are protected from hydrolysis by the introduction of ligands while a soluble polymer provides suitable viscosity for processing of the ceramic precursors. The criteria on the choice of polymers are that they be soluble, have clean decomposition, i.e., no residue, and are compatible with the metal precursors, i.e., they do not precipitate or react to hinder the deposition.

The process of the present invention uses a soluble polymer to assist in the deposition of an initial intermediate metal oxide. Thus, the process can be referred to as a polymer assisted solution deposition process. Inclusion of a soluble polymer with a soluble metal complex or complexes promotes better distribution of the materials during the deposition. Where the polymer and metal complex or complexes are water-soluble, the process can provide an organic-solvent free process. Subsequently, the polymer can be removed by heating at sufficiently high temperatures to leave the intermediate metal oxide film. By using a soluble polymer in conjunction with one or more soluble metal complexes, single or mixed metal oxide films can be prepared. The overall process is an aqueous process that can be organic solvent free. Where the present invention involves an aqueous process, such a process can bes conducted at pH conditions of from about 4 to about 7, more preferably from about 5 to about 7. Such pH ranges can avoid any drawbacks associated with highly acidic processes.

The soluble polymer used in the present process can be polyvinyl alcohol or may be polyethylene glycol, polyacrylic acid, poly(diallyl ammonium chloride) or polyethylenimine. Polyvinyl alcohol is the preferred soluble polymer because of its low decomposition temperature. Typically, the molecular weight of such polyvinyl alcohol can be within the range of from about 13,000 to about 98,000 and be about 80 to 99 or more percent hydrolyzed.

One important function of the soluble polymer is to provide necessary viscosity so that the metal oxide precursor solution can be processed into desired configurations such as thin films. The desired viscosity can be achieved through controlling the solution concentration of the soluble polymers. For high quality homogeneous films, polymer concentrations and the polymer ratio to metal components should be maintained at a proper balance. The rheology of the metal oxide precursor is also important for the morphology and quality of the final metal oxide films. In order to form smooth thin films, the polymer solution must have suitable Theological properties so that the spin-coated films have no undesired patterns associated with polymer Theological properties.

The polymer functions as a chaperone in assisting the formation of the polymer-metal composite and ultimately the high quality metal oxide films for conversion to the semiconductor thin films. This requires that the polymer should also have suitable interactions to metal ions such that no phase separation occurs during the deposition processes. Thereafter, the polymer-metal composite films are calcined to obtain metal oxide films. Thus, the soluble polymer selection should also have suitable decomposition characteristics, e.g., a clean decomposition under calcination conditions, so that the metal oxide is free of side products.

The composition used for the deposition includes the soluble polymer and the soluble metal chelates. In addition, other metals can be included through addition of appropriate soluble metal salts. For example, barium can be added through a soluble barium salt such as barium acetate. Other suitable metal salts may include metal nitrates, metal nitrites, metal oxalates, metal acrylates, and metal coordination complexes.

In addition to water as the solvent for the solution, alcohols such as methanol, ethanol and propanol may be used as the solvent.

The composition is typically maintained at ambient temperatures from about 15° C. to about 30° C., more usually from about 20° C. to about 25° C. Within those temperature ranges, the materials added to the solution are generally soluble.

The metal ratio can be controlled through appropriate addition of soluble metal chelates salts to the composition used for the deposition. Such compositions can generally have a shelf life of more than a year.

The intermediate metal oxide films in the present process can include a metal oxide with a single metal, can be a metal oxide with two metals or may be a metal oxide including three or more metals. Among the intermediate metal oxides preparable in the present process are included cadmium oxide, lead oxide, zinc oxide, titanium oxide, copper oxide, indium oxide and the like. Among the mixed metal oxides preparable by the present process are included a copper oxide—cadmium oxide mixture, an indium oxide—cadmium oxide mixture, a titanium oxide—cadmium oxide mixture, a zinc oxide—cadmium oxide mixture, a copper oxide—gallium oxide—indium oxide mixture and the like. The metal oxide films prepared by the present process can be resistive or conductive depending upon the chemical compositions and microstructures.

The starting composition can be deposited on a desired substrate, e.g., by spray coating, dip coating, spin coating, ink jet printing and the like. Choice of deposition technique can depend upon the shape of the substrate.

After initial deposition of the composition on a substrate, the composition can be initially treated to obtain a coherent coating, e.g., a stable thin film coating. One manner of treatment can be by initially drying via heating the deposited composition to temperatures of from about 50° C. to about 150° C. for from about 15 minutes to several hours, preferably for less than one hour. Another manner of treatment can simply involve spinning the composition to form a coherent coating though removal of solvent.

To obtain the intermediate polymer-free metal oxide thin film, the thin film coating is calcined or heated at high temperatures of from about 250° C. to about 950° C., preferably from about 450° C. to about 650° C. for a period of time sufficient to remove the polymer and leave only the metal oxide thin film.

The intermediate polymer—metal oxide film generally can undergo removal of volatile species during the drying stage and structural rearrangement during the calcination stage.

Subsequently, the metal oxide films can be reacted with selected gases capable of converting the metal oxide films, e.g., to group II-VI and group I-III-VI semiconductive films. For example, Thioacetamide (from Acros) can react with H₂O and generate H₂S. H₂Se gas can be generated by the reaction between Al₂Se₃ (from Alfa Aesar) and H₂O. Moreover, H₂Te can be generated by the reaction between Al₂Te₃ and HCl. In a similar way, thioacetamide and Al₂Se₃ mixed with H₂O with certain ratio can be prepared in a container. Gas such as H₂S and H₂Se will be generated. Metal oxide films can react with these gases in a sealed container. Metal sulfides, selenides or tellurides can be then formed through the reaction between the oxides and H₂S, H₂Se, or H₂Te.

The present invention enables the processing of semiconductive thin films with convenience and flexibility required in industrial fabrication. This process involves making semiconductive thin films from solutions and allows the processing from aqueous solution in a process that can be organic solvent-free.

Microstructures and surface morphology of the films were also characterized with transmission electron microscopy.

A typical formulation for deposition of a cadmium oxide film for subsequent conversion to, e.g., a cadmium sulfide film, includes an aqueous solution containing cadmium nitrate tetrahydrate and polyvinyl alcohol.

In comparison to organic solvent processing, aqueous solution processing offers versatile manipulation of nanostructures through the introduction of micelles, liquid crystals and supramolecular assemblies. The present invention offers advantages over existing chemical solution technologies. Additionally, the approach of the present invention may be expanded to many additional metals.

The present invention is more particularly described in the following examples which are intended as illustrative only, since numerous modifications and variations will be apparent to those skilled in the art.

### EXAMPLE 1

A cadmium sulfide film was prepared as follows. An aqueous cadmium salt solution was prepared by dissolving (20% by weight cadmium salt) of cadmium nitrate tetrahydrate (available from Acros, Fisher Scientific Co.) in water. A total of 1 g of poly(vinyl alcohol) (PVA, available from Sldrich, 87-89 percent hydrolyzed, average MW of 13,000-23,000) was dissolved in 10 ml of water (10% by weight PVA). It was necessary to give the solution sufficient time to completely dissolve (overnight). Optionally, filtration could be used if there are particles or other undissolved solids in the solution. It was found particularly useful to dissolve the polyvinyl alcohol in an excess of water and then concentrate the polymer solution to the desired volume under nitrogen.

The cadmium salt solution was mixed with the aqueous poly(vinyl alcohol) solution at a cadmium salt:PVA weight ratio of 2:1 to yield a transparent metal-salt polymer solution. This solution had a pH between about 6 and 7. This ratio can be varied from about 1:10 to about 10:1.

The resulting solution was used to spin coat thin films onto glass substrates. Spin coating was readily achieved with a spinning speed of 3000 rpm over 60 seconds. (Spin Coater Model 100, from Cost Effective Equipment, a division of Brewer Science, Inc., Rolla, Mo.)

The composite thin films of polymer and metal were then initially heated at about 260° C. for about 10 minutes to immobilize the metal salt polymer film as coherent films. The spinning steps and heating steps were repeated where thicker films were desired. The coherent films were then calcined at 550° C. for 90 minutes under an oxygen atmosphere to yield cadmium oxide films. The color of the cadmium oxide films was orange and the films were conductive. A sufficient amount of thioacetamide (typically 10 mg depending upon the size and thickness of the cadmium oxide film) was placed into a container with a cadmium oxide coated substrate. After sealing the container with a rubber stopper, one ml of water was injected into the container. Hydrogen sulfide gas (H₂S) was generated by the reaction of the water with the thioacetamide. After about 1 hour, the color of the film had changed from orange to yellow. This indicated the formation of a cadmium sulfide film.

### EXAMPLE 2

A cadmium sulfide film was prepared as follows. An aqueous cadmium salt solution was prepared by dissolving (30% by weight cadmium salt) of cadmium nitrate tetrahydrate in water.

The cadmium salt solution was mixed with the 10% by weight aqueous poly(vinyl alcohol) solution at a cadmium salt:PVA weight ratio of 1:1 to yield a transparent metal-salt polymer solution. This solution had a pH between about 6 and 7. This ratio can be varied from about 1:10 to about 10:1. The resulting solution was used to spin coat thin films onto glass substrates with a spinning speed of 3000 rpm.

The substrates coated with metal salt-polymer films were then heated at 550° C. for 90 minutes under an oxygen atmosphere to yield cadmium oxide films. The color of the cadmium oxide films was orange and the films were conductive. A sufficient amount of thioacetamide (about 10 mg) was placed into a container with a cadmium oxide coated substrate. After sealing the container with a rubber stopper, one ml of water was injected into the container. Hydrogen sulfide gas (H₂S) was generated by the reaction of the water with the thioacetamide. After about 1 hour, the color of the film had changed from orange to yellow indicating the formation of a cadmium sulfide film.

### EXAMPLE 3

A cadmium selenide film was prepared as follows. An aqueous cadmium salt solution was prepared by dissolving (30% by weight cadmium salt) of cadmium nitrate tetrahydrate in water.

The cadmium salt solution was mixed with the 10% by weight aqueous poly(vinyl alcohol) solution at a cadmium salt:PVA weight ratio of 2:1 to yield a transparent metal-salt polymer solution. This solution had a pH between about 6 and 7. This ratio can be varied from about 1:10 to about 0:1. The resulting solution was used to spin coat thin films onto glass substrates with a spinning speed of 3000 rpm.

The substrates coated with metal salt-polymer films were then heated at 550° C. for 90 minutes under an oxygen atmosphere to yield cadmium oxide films. The color of the cadmium oxide films was orange and the films were conductive. A sufficient amount of aluminum selenide (Al₂Se₃), about 10 mg, was placed into a container with a cadmium oxide coated substrate. After sealing the container with a rubber stopper, one ml of water was injected into the container. Hydrogen selenide gas (H₂Se) was generated by the reaction of the water with the Al₂Se₃. After about 1 hour, a cadmium selenide film had formed.

### EXAMPLE 4

A zinc sulfide film was prepared as follows. An aqueous zinc salt solution was prepared by dissolving (30% by weight zinc salt) of zinc nitrate hydrate in water.

The zinc salt solution was mixed with the 10% by weight aqueous poly(vinyl alcohol) solution at a zinc salt:PVA weight ratio of 1:1 to yield a transparent metal-salt polymer solution. This solution had a pH between about 6 and 7. This ratio can be varied from about 1:10 to about 10:1. The resulting solution was used to spin coat thin films onto glass substrates with a spinning speed of 3000 rpm.

The substrates coated with metal salt-polymer films were then heated at 550° C. for 90 minutes under an oxygen atmosphere to yield zinc oxide films. The color of the zinc oxide films was nearly transparent. A sufficient amount of thioacetamide (about 5 mg) was placed into a container with a zinc oxide coated substrate. After sealing the container with a rubber stopper, 2 ml of water was injected into the container. Hydrogen sulfide gas (H₂S) was generated by the reaction of the water with the thioacetamide. After about 1 hour, the zinc oxide film had converted to a zinc sulfide film.

### EXAMPLE 5

A lead sulfide film was prepared as follows. An aqueous lead salt solution was prepared by dissolving (20% by weight lead salt) of lead acetate trihydrate in water.

The lead salt solution was mixed with the 10% by weight aqueous poly(vinyl alcohol) solution at a lead salt:PVA weight ratio of 2:1 to yield a transparent metal-salt polymer solution. This solution had a pH between about 6 and 7. This ratio can be varied from about 1:10 to about 10:1. The resulting solution was used to spin coat thin films onto glass substrates with a spinning speed of 6000 rpm.

The composite thin films of polymer and metal were then initially heated at about 260° C. for about 10 minutes to immobilize the metal salt polymer film as coherent films. The substrates were then heated at 550° C. for 90 minutes under an oxygen atmosphere to yield cadmium oxide films. The color of the lead oxide films was almost transparent. A sufficient amount of thioacetamide (about 10 mg) was placed into a container with a lead oxide coated substrate. After sealing the container with a rubber stopper, 2 ml of water was injected into the container. Hydrogen sulfide gas (H₂S) was generated by the reaction of the water with the thioacetamide. After about 1 hour, the color of the film had changed from transparent to black indicating the formation of a lead sulfide film.

### EXAMPLE 6

A composite zinc-cadmium sulfide film was prepared as follows. An aqueous zinc salt-cadmium salt solution was prepared by dissolving (30% by weight zinc salt and cadmium salt in a 1:1 by weight ratio) of zinc nitrate hydrate and cadmium nitrate tetrahydrate in water. This ratio can be varied from about 1:10 to about 10:1.

This zinc salt and cadmium salt solution was mixed with the 10% by weight aqueous poly(vinyl alcohol) solution at a salt:PVA weight ratio of 2:1 to yield a transparent metal-salt polymer solution. This solution had a pH between about 6 and 7. The resulting solution was used to spin coat thin films onto conductive ITO coated glass substrates at a spinning speed of 3000 rpm.

The substrates coated with zinc salt and cadmium salt-polymer films were then heated at 550° C. for 90 minutes under an oxygen atmosphere to yield zinc-cadmium oxide films. The color of the zinc-cadmium oxide films was orange. A sufficient amount of thioacetamide (about 5 mg) was placed into a container with a zinc-cadmium oxide coated substrate. After sealing the container with a rubber stopper, one ml of water was injected into the container. Hydrogen sulfide gas (H₂S) was generated by the reaction of the water with the thioacetamide. After about 1 hour, the zinc-cadmium oxide film had converted to a zinc-cadmium sulfide film.

### EXAMPLE 7

A composite titanium-cadmium sulfide film was prepared as follows. An aqueous titanium salt-cadmium salt solution was prepared by dissolving (30% by weight titanium salt and cadmium salt in a 1:1 by weight ratio) of titanium (IV) (triethanolaminato)-isopropoxide and cadmium nitrate tetrahydrate in water. This ratio can be varied from about 1:10 to about 10:1.

This titanium salt and cadmium salt solution was mixed with the 10% by weight aqueous poly(vinyl alcohol) solution at a salt:PVA weight ratio of 1:1 to yield a transparent metal-salt polymer solution. This solution had a pH between about 6 and 7. The resulting solution was used to spin coat thin films onto conductive ITO coated glass substrates at a spinning speed of 3000 rpm.

The substrates coated with titanium salt and cadmium salt-polymer films were then heated at 550° C. for 90 minutes under an oxygen atmosphere to yield titanium-cadmium oxide films. The color of the titanium-cadmium oxide films was orange. A sufficient amount of thioacetamide (about 5 mg) was placed into a container with a titanium-cadmium oxide coated substrate. After sealing the container with a rubber stopper, one ml of water was injected into the container. Hydrogen sulfide gas (H₂S) was generated by the reaction of the water with the thioacetamide. After about 1 hour, the titanium-cadmium oxide film had converted to a titanium oxide-cadmium sulfide film.

### EXAMPLE 8

A composite copper-cadmium sulfide film was prepared as follows. An aqueous copper salt-cadmium salt solution was prepared by dissolving (20% by weight copper salt and cadmium salt in a 1:1 by weight ratio) of copper (II) chloride dihydrate and cadmium nitrate tetrahydrate in water. This ratio can be varied from about 1:10 to about 10:1.

This copper salt and cadmium salt solution was mixed with the 10% by weight aqueous poly(vinyl alcohol) solution at a salt:PVA weight ratio of 1:1 to yield a transparent metal-salt polymer solution. This solution had a pH between about 6 and 7. The resulting solution was used to spin coat thin films onto conductive ITO coated glass substrates at a spinning speed of 3000 rpm.

The substrates coated with copper salt and cadmium salt-polymer films were then heated at 550° C. for 90 minutes under an oxygen atmosphere to yield copper-cadmium oxide films that may be converted to a copper-cadmium sulfide film in the manner of the prior examples.

### EXAMPLE 9

A composite indium-cadmium sulfide film was prepared as follows. An aqueous indium salt-cadmium salt solution was prepared by dissolving (30% by weight indium salt and cadmium salt in a 1:1 by weight ratio) of indium (III) chloride and cadmium nitrate tetrahydrate in water. This ratio can be varied from about 1:10 to about 10:1.

This indium salt and cadmium salt solution was mixed with the 10% by weight aqueous poly(vinyl alcohol) solution at a salt:PVA weight ratio of 3:1 to yield a transparent metal-salt polymer solution. This solution had a pH between about 6 and 7. The resulting solution was used to spin coat thin films onto conductive ITO coated glass substrates at a spinning speed of 3000 rpm.

The substrates coated with indium salt and cadmium salt-polymer films were then heated at 550° C. for 90 minutes under an oxygen atmosphere to yield indium-cadmium oxide films that may be converted to an indium-cadmium sulfide film in the manner of the prior examples.

### EXAMPLE 10

A composite cadmium sulfide-titanium oxide thin film structure was prepared as follows. An aqueous titanium salt-cadmium salt solution was prepared by dissolving (20% by weight titanium salt) titanium (IV) (triethanolaminato)-isopropoxide in water. Then, it was mixed with a 10% by weight aqueous poly(vinyl alcohol) solution at a salt:PVA weight ratio of 1:1 to yield a transparent metal-salt polymer solution. This solution had a pH between about 6 and 7. This ratio can be varied from about 1:10 to about 10:1. Metal salt-polymer composite films were obtained by spin coating this solution onto conductive ITO substrates at a spinning speed of 3000 rpm. The substrates coated with the metal salt-polymer layers were heated at 550° C. for 90 minutes to yield titanium oxide films.

Then, a cadmium solution was prepared by initially dissolving (20% by weight cadmium salt) cadmium nitrate tetrahydrate in water. Then, it was mixed with a 10% by weight aqueous poly(vinyl alcohol) solution at a salt:PVA weight ratio of 1:1 to yield a transparent metal-salt polymer solution. This solution had a pH between about 6 and 7. Metal salt-polymer composite films were obtained by spin coating this solution onto the titanium oxide coated ITO substrates at a spinning speed of 3000 rpm. The substrates coated with the metal salt-polymer layers were heated at 550° C. for 90 minutes to yield orange colored cadmium oxide films.

A sufficient amount of thioacetamide (about 5 mg) was placed into a container with the cadmium oxide/titanium oxide/ITO composite. After sealing the container with a rubber stopper, one ml of water was injected into the container. Hydrogen sulfide gas (H₂S) was generated by the reaction of the water with the thioacetamide. After about 1 hour, the cadmium oxide layer had converted to a cadmium sulfide layer yielding a hetero-structure of cadmium sulfide/titanium oxide upon the ITO substrate.

### EXAMPLE 11

A composite cadmium sulfide-copper sulfide thin film structure was prepared as follows. An aqueous cadmium salt-cadmium salt solution was prepared by dissolving (20% by weight cadmium salt) cadmium nitrate tetrahydrate in water. Then, it was mixed with a 10% by weight aqueous poly(vinyl alcohol) solution at a salt:PVA weight ratio of 1:1 to yield a transparent metal-salt polymer solution. This solution had a pH between about 6 and 7. This ratio can be varied from about 1:10 to about 10:1. Metal salt-polymer composite films were obtained by spin coating this solution onto conductive ITO substrates at a spinning speed of 3000 rpm. The substrates coated with the metal salt-polymer layers were heated at 550° C. for 90 minutes to yield orange colored cadmium oxide films.

Then, a copper solution was prepared by initially dissolving (20% by weight copper salt) copper (II) chloride in water. Then, it was mixed with a 10% by weight aqueous poly(vinyl alcohol) solution at a salt:PVA weight ratio of 1:1 to yield a transparent metal-salt polymer solution. This solution had a pH between about 6 and 7. Metal salt-polymer composite films were obtained by spin coating this solution onto the cadmium oxide coated ITO substrates at a spinning speed of 3000 rpm. The substrates coated with the metal salt-polymer layers were heated at 550° C. for 90 minutes to yield a topcoat layer of copper oxide.

A sufficient amount of thioacetamide (about 5 mg) was placed into a container with the copper oxide/cadmium oxide/ITO composite. After sealing the container with a rubber stopper, one ml of water was injected into the container. Hydrogen sulfide gas (H₂S) was generated by the reaction of the water with the thioacetamide. After more than one hour, the copper oxide/cadmium oxide/ITO structure had converted to a copper sulfide/cadmium sulfide/ITO substrate hetero-structure.

### EXAMPLE 12

A composite titanium oxide-cadmium selenide thin film structure was prepared as follows. An aqueous titanium salt-cadmium salt solution was prepared by dissolving (20% by weight titanium salt) titanium (IV) (triethanolaminato)-isopropoxide in water. Then, it was mixed with a 10% by weight aqueous poly(vinyl alcohol) solution at a salt:PVA weight ratio of 1:1 to yield a transparent metal-salt polymer solution. This solution had a pH between about 6 and 7. This ratio can be varied from about 1:10 to about 10:1. Metal salt-polymer composite films were obtained by spin coating this solution onto conductive ITO substrates at a spinning speed of 3000 rpm. The substrates coated with the metal salt-polymer layers were heated at 550° C. for 90 minutes to yield titanium oxide films.

Then, a cadmium solution was prepared by initially dissolving (20% by weight cadmium salt) cadmium nitrate tetrahydrate in water. Then, it was mixed with a 10% by weight aqueous poly(vinyl alcohol) solution at a salt:PVA weight ratio of 1:1 to yield a transparent metal-salt polymer solution. This solution had a pH between about 6 and 7. Metal salt-polymer composite films were obtained by spin coating this solution onto the titanium oxide coated ITO substrates at a spinning speed of 3000 rpm. The substrates coated with the metal salt-polymer layers were heated at 550° C. for 90 minutes to yield orange colored cadmium oxide films.

A sufficient amount (about 5 mg) of aluminum selenide (Al₂Se₃) was placed into a container with the cadmium oxide/titanium oxide/ITO composite. After sealing the container with a rubber stopper, one ml of water was injected into the container. Hydrogen sulfide gas (H₂Se) was generated by the reaction of the water with the aluminum selenide. After more than one hour, the cadmium oxide/titanium oxide/ITO composite structure had converted to a cadmium selenide/titanium oxide/ITO composite hetero-structure.

### EXAMPLE 13

A composite cadmium sulfide-cadmium selenide thin film structure was prepared as follows. An aqueous cadmium solution was prepared by initially dissolving (20% by weight cadmium salt) cadmium nitrate tetrahydrate in water. Then, it was mixed with a 10% by weight aqueous poly(vinyl alcohol) solution at a salt:PVA weight ratio of 1:1 to yield a transparent metal-salt polymer solution. This solution had a pH between about 6 and 7. This ratio can be varied from about 1:10 to about 10:1. Metal salt-polymer composite films were obtained by spin coating this solution onto conductive ITO substrates at a spinning speed of 3000 rpm. The substrates coated with the metal salt-polymer layers were heated at 550° C. for 90 minutes to yield orange colored cadmium oxide films.

A sufficient amount of thioacetamide (about 5 mg) and of aluminum selenide (about 5 mg) was placed into a container with the cadmium oxide/ITO composite. The weight ratio of sulfide to selenide may be varied from about 20:1 to about 1:20 as desired. After sealing the container with a rubber stopper, one ml of water was injected into the container. Both hydrogen sulfide gas and hydrogen selenide gas were generated by the reaction of the water with the thioacetamide and aluminum selenide. After more than about one hour, the cadmium oxide layer had converted to a cadmium sulfide and cadmium selenide mixture upon the ITO substrate.

### EXAMPLE 14

A zinc selenide film was prepared as follows. An aqueous zinc salt solution was prepared by dissolving (20% by weight zinc salt) zinc nitrate hydrate in water.

The zinc salt solution was mixed with a 10% by weight aqueous poly(vinyl alcohol) solution at a zinc salt:PVA weight ratio of 1:1 to yield a transparent metal-salt polymer solution. This solution had a pH between about 6 and 7. This ratio can be varied from about 1:10 to about 10:1. The resulting solution was used to spin coat thin films onto glass substrates at a spinning speed of 3000 rpm.

The substrates coated with the metal salt-polymer films were heated at 550° C. for 90 minutes under an oxygen atmosphere to yield zinc oxide films. The color of the zinc oxide films was nearly transparent. A sufficient amount (about 10 mg) of aluminum selenide (Al₂Se₃) was placed into a container with the zinc oxide coated substrate. After sealing the container with a rubber stopper, one ml of water was injected into the container. Hydrogen sulfide gas (H₂Se) was generated by the reaction of the water with the aluminum selenide. After more than one hour, the zinc oxide film had converted to a zinc selenide film.

Examples 1 through 14 demonstrate that semiconductive films can be formed in the process of the present invention.

Although the present invention has been described with reference to specific details, it is not intended that such details should be regarded as limitations upon the scope of the invention, except as and to the extent that they are included in the accompanying claims.

What is claimed is:

1. A process of preparing a semiconductive film comprising:
applying a solution containing a soluble polymer and a soluble metal precursor onto a substrate to form a polymer and metal containing layer thereon;
treating said substrate including said polymer and metal containing layer for a time to form a coherent composite film;
heating said substrate in an oxygen-containing atmosphere at temperatures characterized as sufficient to remove said polymer from said composite film and form a metal oxide film; and,
reacting said metal oxide film with a sulfur-, selenium- or tellurium-containing gas under conditions sufficient to form a semiconductive film.

2. The process of claim 1 wherein said solution is an aqueous solution having a pH of from about 4 to about 7.

3. The process of claim 1 wherein said semiconductive film contains a single metal selected from the group consisting of cadmium, indium, zinc, copper and titanium.

4. The process of claim 1 wherein said metal oxide film is cadmium oxide and said semiconductive film is selected from the group consisting of cadmium sulfide, cadmium selenide, cadmium telluride or mixtures thereof.

5. The process of claim 2 wherein said process is organic-solvent free.

6. The process of claim 1 wherein said metal oxide film is zinc oxide and said semiconductive film is selected from the group consisting of zinc sulfide, zinc selenide, zinc tellenide or mixtures thereof.

7. The process of claim 1 wherein said semiconductive film is a dye-sensitized titanium oxide film.

8. The process of claim 1 wherein said metal oxide film is a mixed metal oxide selected from the group consisting of zinc and cadmium, copper and indium, copper and gallium, cadmium and indium, and copper, gallium and indium.

9. The process of claim 8 wherein said semiconductive film is selected from the group consisting of zinc cadmium sulfide, zinc cadmium selenide, zinc cadmium telluride or mixtures thereof.

10. The process of claim 8 wherein said semiconductive film is selected from the group consisting of copper indium sulfide, copper indium selenide, copper indium telluride or mixtures thereof.

11. The process of claim 8 wherein said semiconductive film is selected from the group consisting of cadmium indium sulfide, cadmium indium selenide, cadmium indium telluride or mixtures thereof.

12. The process of claim 8 wherein said semiconductive film is selected from the group consisting of copper gallium sulfide, copper gallium selenide, copper gallium telluride or mixtures thereof.

13. The process of claim 8 wherein said semiconductive film is copper gallium indium selenide.

14. The process of claim 1 wherein said soluble polymer is selected from the group consisting of poly(vinyl alcohol), polyethylene glycol, poly(acrylic acid), poly(diallyldimethyl ammonium chloride), and polyethylenimine.

15. The process of claim 1 wherein said soluble polymer is polyvinyl alcohol.

16. The process of claim 1 wherein said soluble precursor includes a combination of.

17. The process of claim 1 wherein said treating includes drying at temperatures characterized as insufficient to remove said polymer but sufficient to form the coherent composite film.

18. A composition of matter comprising a solution of a water-soluble metal compound and a water-soluble polymer, said solution having a pH of from about 4 to about 7 and characterized as organic-solvent free.

19. The composition of claim 18 wherein said water-soluble polymer is selected from the group consisting of polyvinyl alcohol, polyethylene glycol, poly(acrylic acid), poly(diallyldimethyl ammonium chloride), and polyethylenimine.

20. The composition of claim 18 wherein said water-soluble metal contains a single metal selected from the group consisting of cadmium, indium, zinc, copper, gallium and titanium.
